(19) United States
(12) Patent Application Publication
(10) Pub. No.: US 2016/0374196 A1
(43) Pub. Date: Dec. 22, 2016

(54) PRINTED CIRCUIT BOARD AND METHOD OF MANUFACTURING THE SAME

(71) Applicant: Samsung Electro-Mechanics Co., Ltd., Suwon-si (KR)

(72) Inventors: Jae-Ean LEE, Busan (KR); Jee-Soo MOK, Yongin-si (KR); Young-Gwan KO, Seoul (KR); Soon-Oh JUNG, Yongin-si (KR); Kyung-Hwan KO, Gimhae (KR); Yong-Ho BAEK, Seoul (KR)

(73) Assignee: Samsung Electro-Mechanics Co., Ltd., Suwon-si (KR)

(21) Appl. No.: 15/133,944

(22) Filed: Apr. 20, 2016

(30) Foreign Application Priority Data
Jun. 18, 2015 (KR) 10-2015-0086884

(51) Int. Cl. H05K 1/02; H05K 3/46; H05K 3/40; H05K 1/11

(52) U.S. Cl. CPC H05K 1/0298; H05K 1/112; H05K 3/4697; H05K 3/4644; H05K 3/4007; H05K 2201/09036

(57) ABSTRACT

A printed circuit board includes: a first insulating layer; a first circuit layer disposed above the first insulating layer; a second insulating layer disposed above the first insulating layer; a second circuit layer disposed above the second insulating layer and constructed of a photosensitive material; and a protective layer disposed above the second insulating layer and surrounding the second circuit layer, wherein the protective layer includes a tunnel type cavity and exposes a portion of the second circuit layer to an outside environment, and wherein the second insulating layer exposes a portion of the first circuit layer located below the cavity to an outside environment.

### CROSS-REFERENCE TO RELATED APPLICATION(S)

This application claims the benefit under 35 USC 119(a) of Korean Patent Application No. 10-2015-0086884, filed on Jun. 18, 2015 in the Korean Intellectual Property Office, the entire disclosure of which is incorporated herein by reference for all purposes.

### BACKGROUND

1. Field

The following description relates to a printed circuit board and a method of manufacturing the same.

2. Description of Related Art

Meeting with technical requirements associated with mobile phones and other electronic apparatuses in the field of information technology that have become increasingly multi-functional, lighter, thinner and smaller, there have been heightened demands for inserting integrated circuits, semiconductor chips or various electronic elements, such as active devices and passive devices, in a board. Recently, various methods of embedding a component in a board have been developed.

A typical component embedded board has a cavity formed in an insulating layer of the board and has various components, integrated circuits and/or semiconductor chips inserted in the cavity. U.S. Pat. No. 7,886,433 describes an example of a method of manufacturing a component-embedded printed circuit board.

### SUMMARY

This Summary is provided to introduce a selection of concepts in a simplified form that are further described below in the Detailed Description. This Summary is not intended to identify key features or essential features of the claimed subject matter, nor is it intended to be used as an aid in determining the scope of the claimed subject matter.

According to one general aspect, a printed circuit board includes: a first insulating layer; a first circuit layer disposed above the first insulating layer; a second insulating layer disposed above the first insulating layer; a second circuit layer disposed above the second insulating layer and constructed of a photosensitive material; and a protective layer disposed above the second insulating layer and surrounding the second circuit layer, wherein the protective layer includes a tunnel type cavity and exposes a portion of the second circuit layer to an outside environment, and wherein the second insulating layer exposes a portion of the first circuit layer located below the cavity to an outside environment.

The second insulating layer may be disposed above the entire first insulating layer.

The second insulating layer may be exposed to the outside environment by the cavity.

The second insulating layer may surround the first circuit layer below the cavity and may expose a portion of an upper surface of the first circuit layer to the outside environment.

The second insulating layer may be disposed in an area above the first insulating layer excluding an area below the cavity.

The first insulating layer may be exposed to the outside by the cavity.

The printed circuit board may further include a surface-treated layer formed above the portion of the first circuit layer exposed to the outside environment and the portion of the second circuit layer exposed to the outside environment.

The first circuit layer may form a connection pad in the cavity.

According to another general aspect, a method of manufacturing a printed circuit board includes: forming a first circuit layer above a first insulating layer including a cavity area; forming a second insulating layer above the first insulating layer, the second insulating layer being constructed of a photosensitive material; forming a second circuit layer in an area above the second insulating layer excluding the cavity area; and forming a protective layer above the second insulating layer to surround the second circuit layer, the protective layer including a cavity formed in the cavity area, wherein the protective layer is exposes a portion of the second circuit layer to an outside environment, and wherein the second insulating layer exposes the first circuit layer to the outside environment in the cavity area.

The forming of the second insulating layer may include forming the second insulating layer above the entire first insulating layer.

The forming of the protective layer may include exposing the second insulating layer to the outside environment in the cavity.

The forming of the second insulating layer may include forming the second insulating layer to surround the first circuit layer in the cavity area and to expose a portion of an upper surface of the first circuit layer to the outside environment.

The forming of the second insulating layer may include forming the second insulating layer in an area above the first insulating layer excluding the cavity area.

The forming of the protective layer may include exposing the first insulating layer to the outside by the cavity of the protective layer.

The method may further include forming a surface-treated layer above the portion of the first circuit layer exposed to the outside environment and the portion of the second circuit layer exposed to the outside environment.

The first circuit layer may form a connection pad in the cavity.

Other features and aspects will be apparent from the following detailed description, the drawings, and the claims.

### BRIEF DESCRIPTION OF THE DRAWINGS

FIG. 1 illustrates an example of a printed circuit board.

FIG. 2 is a flow diagram illustrating a method of manufacturing the printed circuit board of FIG. 1.

FIG. 3-19 are cross-sectional views illustrating example processes used in the method of manufacturing the printed circuit board of FIG. 1.

FIG. 20 illustrates another example of a printed circuit board.

FIGS. 21-23 are cross-sectional views illustrating example processes used in the method of manufacturing the printed circuit board of FIG. 20.

Throughout the drawings and the detailed description, the same reference numerals refer to the same elements. The drawings may not be to scale, and the relative size, proportions, and depiction of elements in the drawings may be exaggerated for clarity, illustration, and convenience.

### DETAILED DESCRIPTION

The following detailed description is provided to assist the reader in gaining a comprehensive understanding of the methods, apparatuses, and/or systems described herein. However, various changes, modifications, and equivalents of the methods, apparatuses, and/or systems described herein will be apparent to one of ordinary skill in the art. The sequences of operations described herein are merely examples, and are not limited to those set forth herein, but may be changed as will be apparent to one of ordinary skill in the art, with the exception of operations necessarily occurring in a certain order. Also, descriptions of functions and constructions that are well known to one of ordinary skill in the art may be omitted for increased clarity and conciseness.

The features described herein may be embodied in different forms, and are not to be construed as being limited to the examples described herein. Rather, the examples described herein have been provided so that this disclosure will be thorough and complete, and will convey the full scope of the disclosure to one of ordinary skill in the art.

Terms such as “first”, “second”, “upper” and “lower” are be used in describing various elements, but the above elements shall not be restricted to the above terms. The above terms are used only to distinguish one element from the other. In the accompanying drawings, some elements may be exaggerated, omitted or briefly illustrated, and the dimensions of the elements do not necessarily reflect the actual dimensions of these elements.

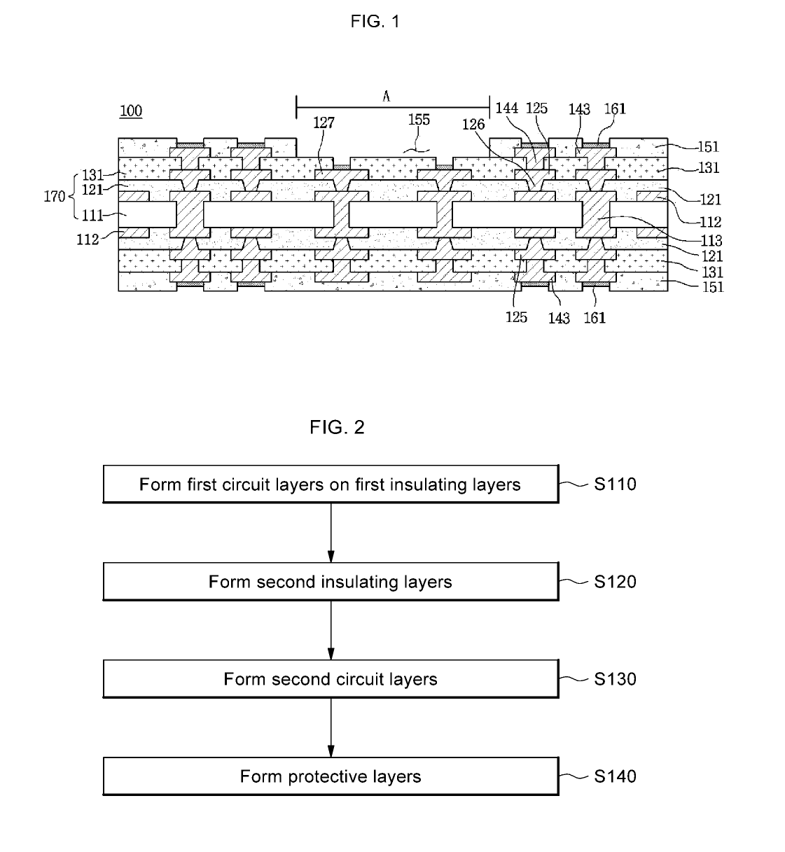

FIG. 1 illustrates a printed circuit board 100 according to an example.

Referring to FIG. 1, a printed circuit board 100 includes an insulating layer 170, upper and lower inner circuit layers 112, upper and lower first circuit layers 125, upper and lower second circuit layers 143, upper and lower protective layers 151, and upper and lower surface-treated layers 161.

The insulating layer 170 includes a core insulating layer 111, upper and lower first insulating layers 121, and upper and lower second insulating layers 131.

The upper first insulating layer 121 and the upper second insulating layer 131 are successively laminated above the core insulating layer 111. The lower first insulating layer 121 and the lower second insulating layer 131 are successively laminated below the core insulating layer 111.

According to an embodiment, the core insulating layer 111, the first insulating layers 121 and the second insulating layers 131 are constructed of a composite polymer resin that is commonly used for an interlayer insulating material. For instance, the core insulating layer 111 and the first insulating layers 121 may be constructed of an epoxy resin, for example, a prepreg, an ajinomoto build-up film (ABF), flame retardant 4 (FR-4) or bismaleimide triazine (BT). However, the material forming the core insulating layer 111 and the first insulating layers 121 is not restricted to what is described herein and may be selected among insulating materials known in the field of circuit boards. In an embodiment, the second insulating layers 131 are made of a photosensitive material.

The upper first insulating layer 121 is formed above the core insulating layer 111 to embed the upper inner circuit layer 112. The lower first insulating layer 121 is formed below the core insulating layer 111 to embed the lower inner circuit layer 112.

The upper inner circuit layer 112 is formed above the core insulating layer 111. The lower inner circuit layer 112 is formed below the core insulating layer 111. The inner circuit layers 112 are made of a conductive material. For instance, the inner circuit layers 112 may be made of copper or another conductive material known in the field of circuit boards.

The printed circuit board 100 further includes a through-via 113 formed to penetrate the core insulating layer 111. The through-via 113 electrically connects the upper inner circuit layer 112 with the lower inner circuit layer 112. The through-via 113 is made of a conductive material such as copper, or another conductive material known in the field of circuit boards.

According to an embodiment, the upper first circuit layer 125 is formed above the upper first insulating layer 121. The lower first circuit layer 125 is formed below the lower first insulating layer 121.

A portion of the upper first circuit layer 125 is placed in a cavity 155. Moreover, the portion of the upper first circuit layer 125 that is disposed in the cavity 155 includes connection pads 127 having upper surfaces that are partially exposed by the upper second insulating layer 131. The connection pads 127 are elements that are electrically connected with an electronic component (not shown), which is later disposed on the printed circuit board 100. The first circuit layers 125 are constructed of copper or another material known in the field of circuit boards.

The upper second circuit layer 143 is formed above the upper second insulating layer 131. In addition, the lower second circuit layer 143 is formed below the lower second insulating layer 131. The second circuit layers 143 are constructed of copper or another material known in the field of circuit boards.

The upper protective layer 151 is formed above the upper second insulating layer 131 and includes the cavity 155. The cavity 155 is formed to penetrate the upper protective layer 151. Moreover, the upper protective layer 151 includes the upper surface-treated layer 161, which is formed above the upper second insulating layer 131 and the upper first circuit layer 125, and is exposed to the outside environment by the cavity 155. In addition, the lower protective layer 151 is formed below the lower second insulating layer 131.

The upper and lower protective layers 151 are formed to surround the upper and lower second circuit layers 143, respectively. The upper second circuit layer 143, which needs to be electrically connected with an external component (not shown), is formed to have the upper surface-treated layer 161, which is formed above the second circuit layer 143, exposed to the outside environment. When soldering is performed for electrical connection between the external component (not shown) and the upper second circuit layer 143, the upper protective layer 151 protects adjacent portions of the upper second circuit layer 143 that is electrically connected with the external component. Moreover, the protective layers 151 prevent the second circuit layers 143 from being oxidized and corroded by being exposed to the outside. According to an embodiment, the protective layers 151 are constructed of a heat-resistant coating material. For instance, the protective layer 151 may be made of a solder resist.

The upper surface-treated layer 161 is formed above the portions of the upper first circuit layer 125 and the upper second circuit layer 143 that are exposed to the outside. Referring to FIG. 1, the upper surface-treated layer 161 is not formed throughout the upper faces of the connection pads 127 but is formed on only portions of the upper faces of the connection pads 127. The surface-treated layers 161 function to protect the first circuit layers 125 and the second circuit layers 143 from the outside environment. Moreover, the surface-treated layers 161 prevent the first circuit layers 125 and the second circuit layers 143 from being oxidized and corroded.

According to an embodiment, the surface-treated layers 161 may include at least one of organic solderability preservatives (OSP), electroless nickel immersion gold (ENIG), nickel, palladium, gold, tin, lead-free solder, and silver. Moreover, the surface-treated layers 161 may be constructed of any other material known in the field of circuit boards that is capable of protecting an exposed circuit layer. Moreover, in case the second circuit layers 143 having the surface-treated layers 161 formed thereon need to be electrically connected with an outside, the surface-treated layers 161 may be constructed of a conductive material among the above-described materials.

The printed circuit board 100 includes upper and lower first vias 126 that are formed inside the insulating layer 170. The upper first vias 126 electrically connect the upper inner circuit layer 112 with the upper first circuit layer 125, and the lower first vias electrically connect the lower inner circuit layer 112 with the lower first circuit layer 125.

The printed circuit board 100 further includes upper and lower second vias 144 that are formed inside the insulating layer 170. The upper second vias electrically connect the upper first circuit layer 125 with the upper second circuit layer 143, and the lower second vias electrically connect the lower first circuit layer 125 with the lower second circuit layer 143. Moreover, it is possible that one or more vias make an electrical connection between circuit layers, including any circuit layer not illustrated herein, formed in the printed circuit board 100. The second vias 144 are constructed of a conductive material known in the field of circuit boards.

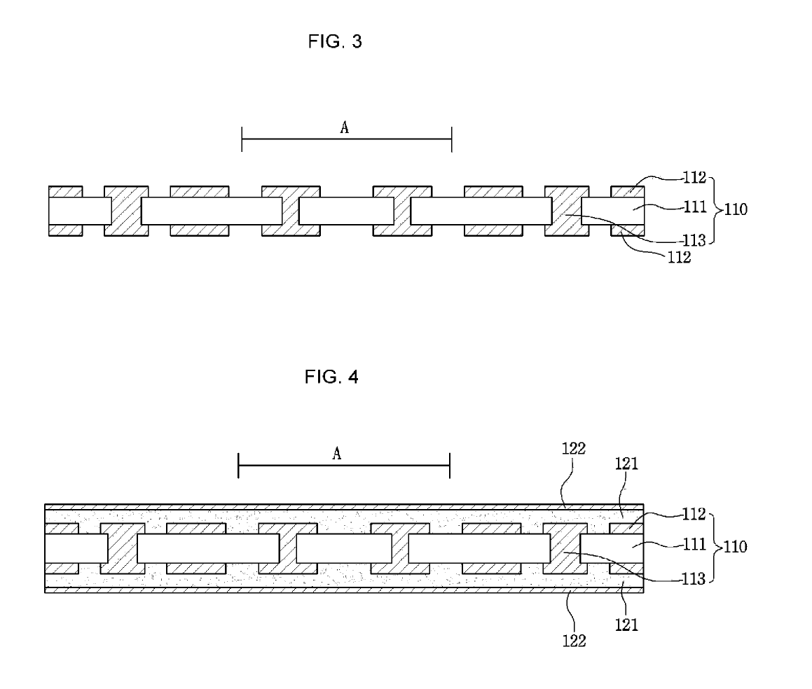

FIG. 2 is a flow diagram illustrating a method of manufacturing the printed circuit board 100 in accordance with an embodiment, and FIGS. 3-19 are cross-sectional views illustrating example processes performed in an example of the method of manufacturing the printed circuit board 100. The flow diagram shown in FIG. 2 of the method of manufacturing the printed circuit board 100 will be described hereinafter with reference to FIGS. 3-19.

Referring to FIGS. 3-9, the first circuit layers 125 are formed on the first insulating layers 121 (operation S110 in FIG. 2).

Referring to FIG. 3, a core board 110 is formed first.

The core board 110 includes the upper and lower inner circuit layers 112 formed on the core insulating layer 111.

According to an embodiment, the core insulating layer 111 is constructed of a composite polymer resin that is commonly used for an interlayer insulating material. For instance, the core insulating layer 111 may be constructed of an epoxy resin, for example, a prepreg, an ajinomoto build-up film (ABF), flame retardant 4 (FR-4) or bismaleimide triazine (BT). However, the material forming the core insulating layer 111 is not restricted to what is described herein and may be selected among insulating materials known in the field of circuit boards.

The upper and lower inner circuit layers 112 are respectively formed above and below the core insulating layer 111. The inner circuit layers 112 are made of a conductive material such as copper, or another conductive material known in the field of circuit boards.

The core board 110 further includes the through-via 113 formed to penetrate the core insulating layer 111. The through-via 113 electrically connects the upper inner circuit layer 112 with the lower inner circuit layer 112.

The core board 110 may be formed using any method known in the field of circuit boards. For instance, it is possible to form the core board 110 by applying one of a tenting method, a semi additive process (SAP) and a modified semi additive process (MSAP).

Referring to FIG. 4, the upper and lower first insulating layers 121 are respectively formed above and below the core board 110.

According to an embodiment, the upper first insulating layer 121 is laminated above the core insulating layer 111 while having an upper first metal layer 122 formed above the upper first insulating layer 121. The lower first insulating layer 121 is laminated below the core insulating layer 111 while having a lower first metal layer 122 formed below the lower first insulating layer 121. Accordingly, the upper and lower first insulating layers 121 are formed to embed the upper and lower inner circuit layers 112, respectively.

According to an embodiment, the first insulating layer 121 is constructed of a composite polymer resin that is commonly used for an interlayer insulating material. For instance, the first insulating layer 121 may be constructed of an epoxy resin, for example, a prepreg, an ajinomoto build-up film (ABF), flame retardant 4 (FR-4) or bismaleimide triazine (BT). However, the material forming the first insulating layer 121 is not restricted to what is described herein and may be selected among insulating materials known in the field of circuit boards.

According to an embodiment, the first metal layers 122 are constructed of copper or another conductive metal used in the field of circuit boards.

Although it is described that the first insulating layers 121 having the first metal layers 122 formed thereon are laminated on the core board 110, this is merely an example and shall not restrict the method of forming the first insulating layers 121. It is possible for anyone ordinarily skilled in the art to choose to laminate the first insulating layers 121 on the core board 110 while the first metal layer 122 is omitted.

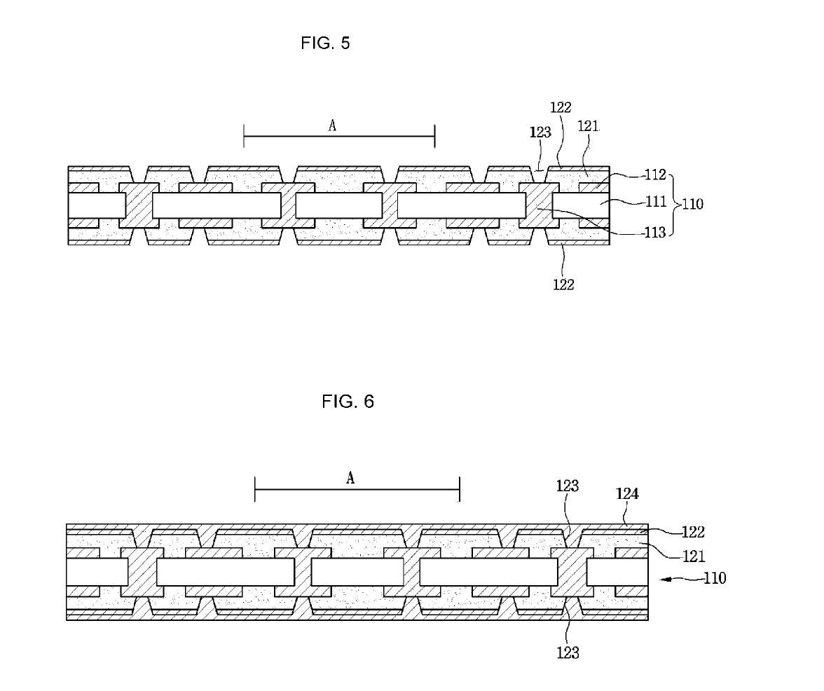

Referring to FIG. 5, upper first via holes 123 are formed above the upper inner circuit layer 112, and are formed to penetrate the upper first insulating layer 121 and the upper first metal layer 122. Lower first via holes 123 are formed below the lower inner circuit layer 112, and are formed to penetrate the lower first insulating layer 121 and the lower first metal layer 122. Accordingly, portions of the upper and lower inner circuit layers 112 are exposed to the outside environment by the upper and lower fist via holes 123, respectively. The first via holes 123 may be formed using a laser drill. Alternatively, the first via holes 123 may be formed using any method of forming a via hole known in the field of circuit boards.

Referring to FIG. 6, upper and lower first plated layers 124 are formed in the upper and lower first via holes 123, respectively, by performing electroplating. The upper first plated layer 124 is formed above the upper first metal layer 122 and the lower first plated layer 124 is formed below the lower first metal layer 122. The first plated layers 124 are constructed of copper or another conductive metal used in the field of circuit boards.

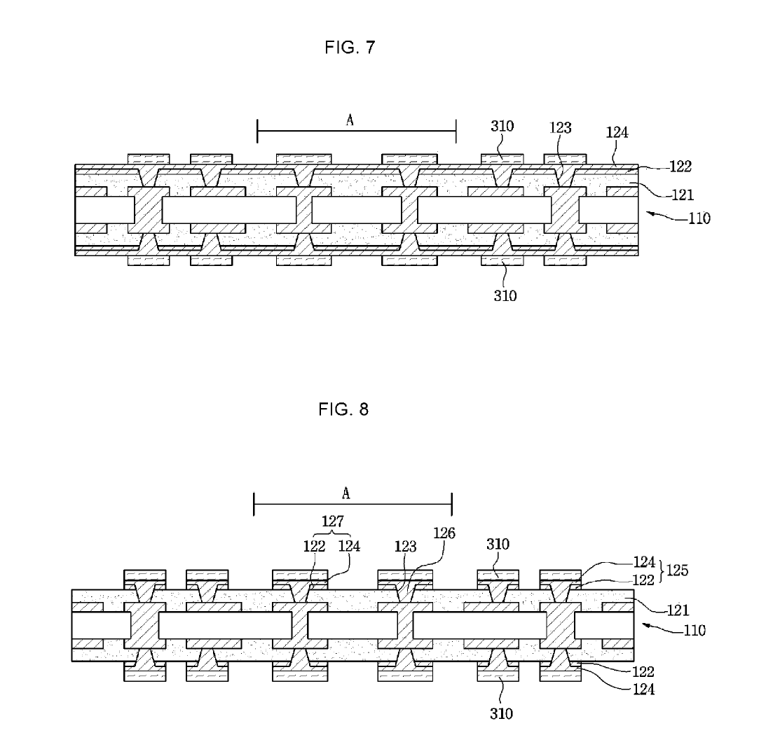

Referring to FIG. 7, an upper first plated resist 310 is formed above the first plated layer 124 that is formed above the core board 110. Additionally, a lower first plated resist 310 is formed below the lower first plated layer 124.

The first plated resists 310 are configured to protect portions where the first circuit layers 125 (shown in FIG. 1) are to be formed and to expose portions that are to be removed. The first plated resists 310 may constructed of any material for a plated resist known in the field of circuit boards.

Referring to FIG. 8, the upper and lower first circuit layers 125 and the upper and lower first vias 126 are formed.

The first circuit layers 125 are formed by patterning the first plated layers 124 (shown in FIG. 7) and the first metal layers 122 (shown in FIG. 7). The portions of the upper and lower first plated layers 124 formed inside the upper and lower first via holes 123 becomes the upper and lower first vias 126, respectively.

The upper first circuit layer 125 includes connection pads 127. The connection pads 127 are elements that are electrically connected with an electronic component (not shown), which is to be disposed on the printed circuit board 100 later. The connection pads 127 are located in a cavity area A, which is an area where a cavity (not shown) is to be formed later.

In an embodiment, the first circuit layers 125 may be formed using a tenting method. However, the method of forming the first circuit layers 125 is not restricted to the tenting method, and it is possible to form the first circuit layers 125 using any method of forming a circuit layer known in the field of circuit board. Hereinafter, the first circuit layers 125 will be illustrated without distinguishing the first circuit layers 125 into the first plated layers 124 and the first metal layers 122.

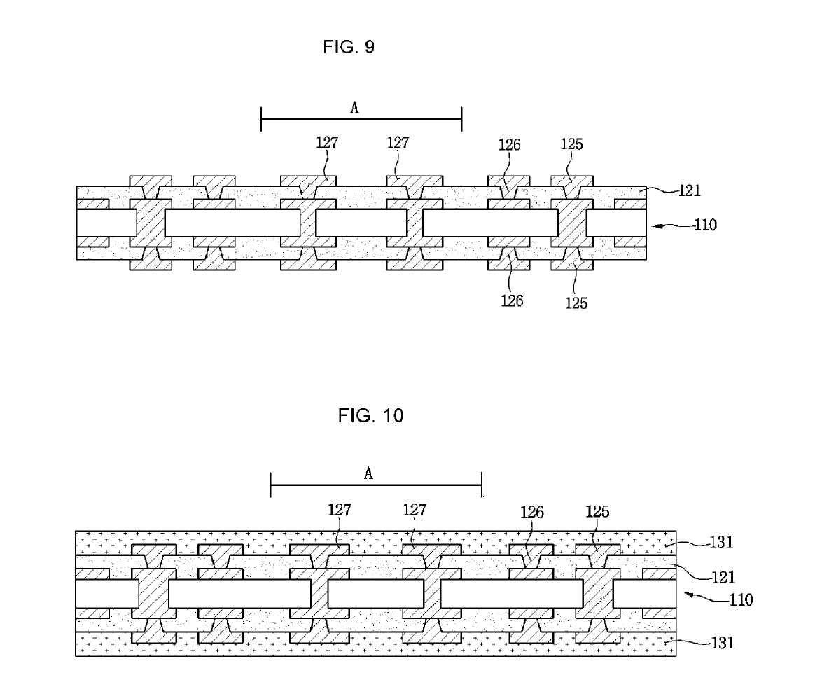

Referring to FIG. 9, the first plated resists 310 (shown in FIG. 8) are removed.

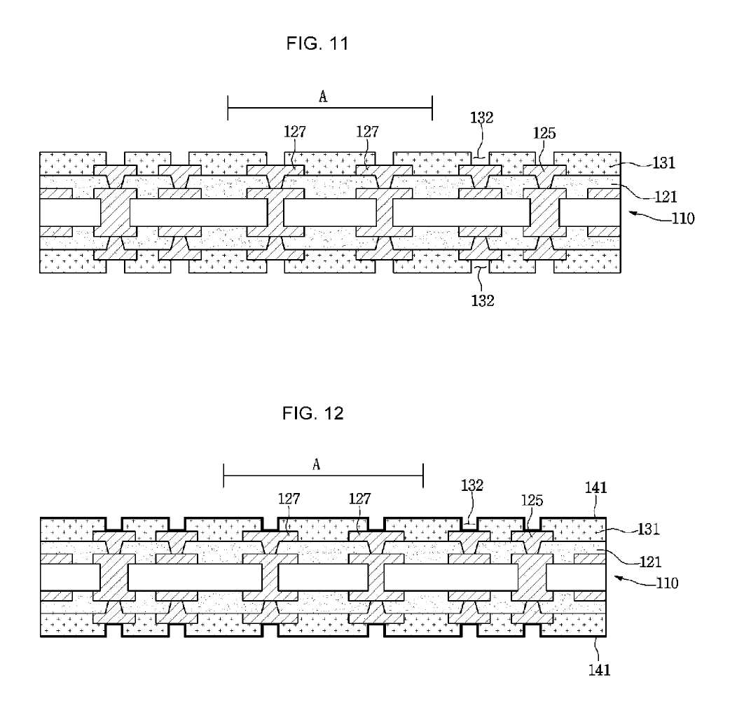

Referring to FIG. 10 and FIG. 11, the upper and lower second insulating layers 131 are formed (operation S120 in FIG. 2).

Referring to FIG. 10, the upper second insulating layer 131 is formed above the upper first insulating layer 121, and the lower second insulating layer 131 is formed below the lower first insulating layer 121. The second insulating layers 131 formed as described above are formed to embed the first circuit layers 125 formed on the first insulating layers 121.

The second insulating layers 131 may be constructed of a photosensitive material among insulating materials known in the field of circuit boards. Moreover, the second insulating layers 131 may be formed using any method of forming an insulating layer known in the field of circuit boards.

Referring to FIG. 11, the second insulating layers 131 are patterned by performing exposure and development processes. The portion of the upper second insulating layer 131 formed in the cavity area A by these processes is patterned to expose the connection pads 127 to the outside environment. Moreover, upper and lower second via holes 132 are formed in areas of the upper and lower second insulating layers 131 excluding the cavity area A.

According to an embodiment, the second insulating layers 131 are constructed of a photosensitive material and are patterned using exposure and development processes. Accordingly, since the conventional punched prepreg is not used, it is possible to omit heating and pressing processes for laminating the prepreg. Therefore, by using the upper second insulating layer 131 constructed of the photosensitive material, it is possible to prevent the problem caused by the prepreg flowing into the cavity area A when the prepreg is heated and pressed.

Moreover, the upper second insulating layer 131 functions as a solder resist layer for protecting the upper first circuit layer 125 in the cavity area A. That is, the upper second insulating layer 131 is substituted for a conventional solder resist layer for protecting the upper first circuit layer 125 in the cavity area A. Therefore, it is possible to omit an additional process of forming the solder resist layer in the cavity area A.

Referring to FIGS. 12-16, the second circuit layers 143 are formed (operation S130 in FIG. 2).

Referring to FIG. 12, an upper seed layer 141 is formed above the upper second insulating layer 131, on inner walls of the upper second via holes 132 and above the portions of the upper first circuit layer 125 exposed to the outside environment. On the lower side of the core board 110, a lower seed layer 141 is formed below the lower second insulating layer 131, on inner walls of the lower second via holes 132 and below the portions of the lower first circuit layer 125 exposed to the outside environment.

The seed layers 141 are formed using a method known in the field of circuit boards. For example, the seed layers 141 may be formed through a wet plating method such as, for example, electroless plating. Alternatively, the seed layers 141 may be formed using a dry plating method such as, for example, sputtering.

Referring to FIG. 13, on the upper side of the core board 110, an upper second plated resist 320 is formed above the upper second insulating layer 131. On the lower side of the core board 110, a lower second plated resist 320 is formed below the lower second insulating layer 131.

The second plated resists 320 may be constructed of a dry film. However, the material for the second plated resists 320 is not restricted to a dry film, and the second plated resists 320 may be constructed of any material for a plated resist known in the field of circuit patterns.

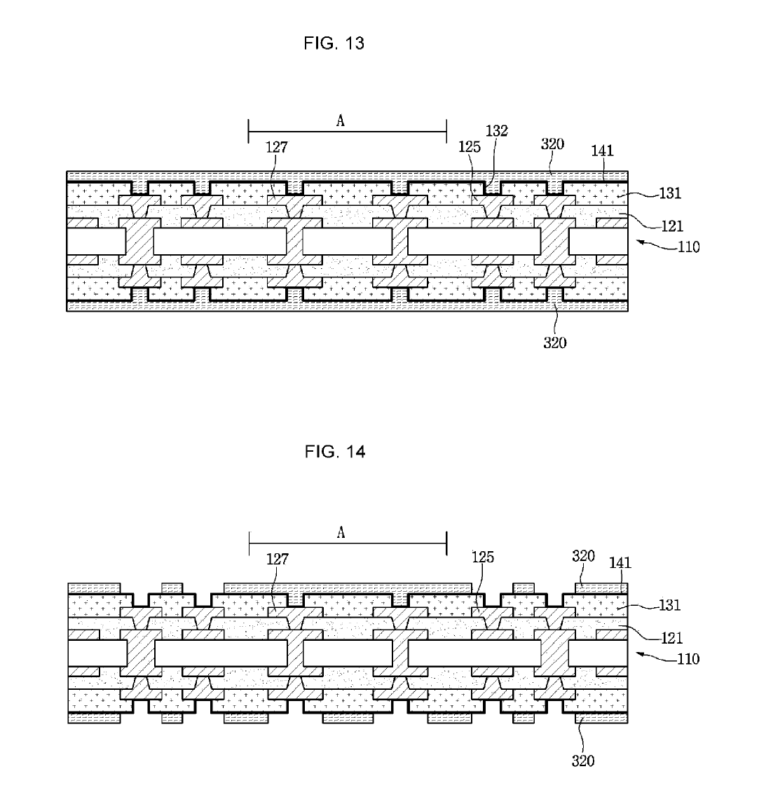

Referring to FIG. 14, the second plated resists 320 are patterned to have openings formed in areas where the second circuit layers 143 (shown in FIG. 1) are to be formed later. The second plated resists 320 are formed to protect the first circuit layers 125 and the portion of the upper seed layer 141 formed in the cavity area A from the outside environment.

The second plated resists 320 may be patterned using exposure and development processes. However, the method of patterning the second plated resists 320 may vary depending on the material used for the second plated resists 320.

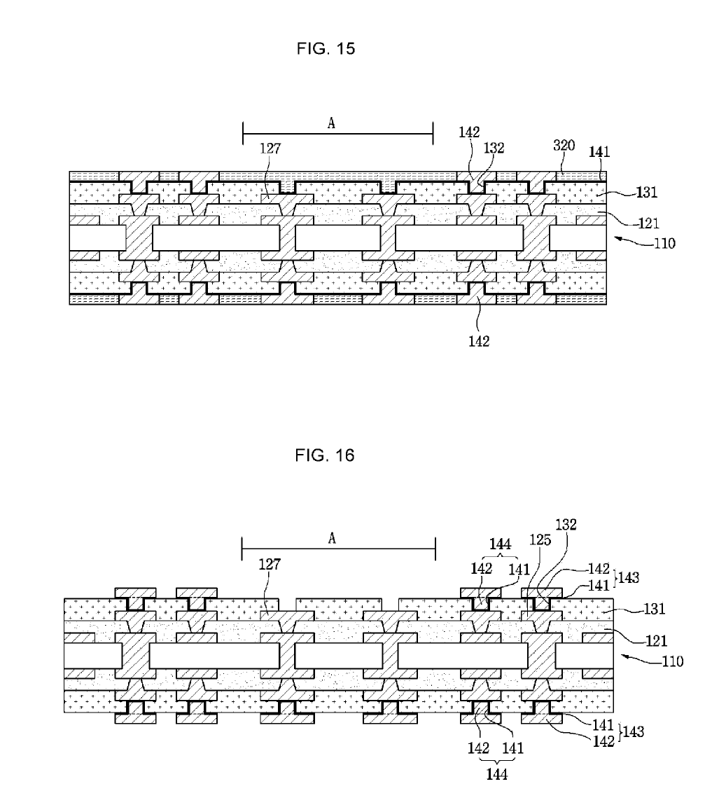

Referring to FIG. 15, upper and lower second plated layers 142 are formed through electroplating. The upper second plated layer 142 is formed in the upper second via holes 132 and above the upper seed layer 141. The lower second plated layer 142 is formed in the lower second via holes 132 and below the lower seed layer 141. The second plated layers 142 are constructed, for example, of copper or another conductive metal used in the field of circuit boards.

When the second plated layers 142 is formed, the upper second plated resist 320 prevents the upper second plated layer 142 from being formed above the upper seed layer 141 in the cavity area A.

Referring to FIG. 16, the second plated resists 320 (shown in FIG. 15) and the portions of the seed layer 141 that are exposed to the outside environment are removed. More specifically, as the second plated resists 320 are removed, portions of the seed layers 141 are exposed to the outside environment. Accordingly, the exposed portions of the seed layer 141 are removed.

The seed layers 141 may be removed by a method known in the field of circuit boards. For instance, the seed layers 141 may be removed using a quick etching method or a flash etching method.

Once the seed layers 141 are removed, upper and lower second vias 144 and upper and lower second circuit layer 143 are formed. That is, the seed layers 141 and the second plated layers 142 formed in the second via holes 132 become the second vias 144. Moreover, on the upper side of the core board 110, the upper seed layer 141 and the upper second plated layer 142 formed above the upper second insulating layer 131 become the upper second circuit layer 143. Similarly, on the lower side of the core board 110, the lower seed layer 141 and the lower second plated layer 142 formed below the lower second insulating layer 131 become the lower second circuit layer 143. Moreover, the seed layers 141 and the second plated layers 142 formed in the second via holes 132 become the second vias 144. Hereinafter, the second circuit layers 143 will be illustrated without distinguishing the second circuit layers 143 into the second plated layers 142 and the seed layers 141.

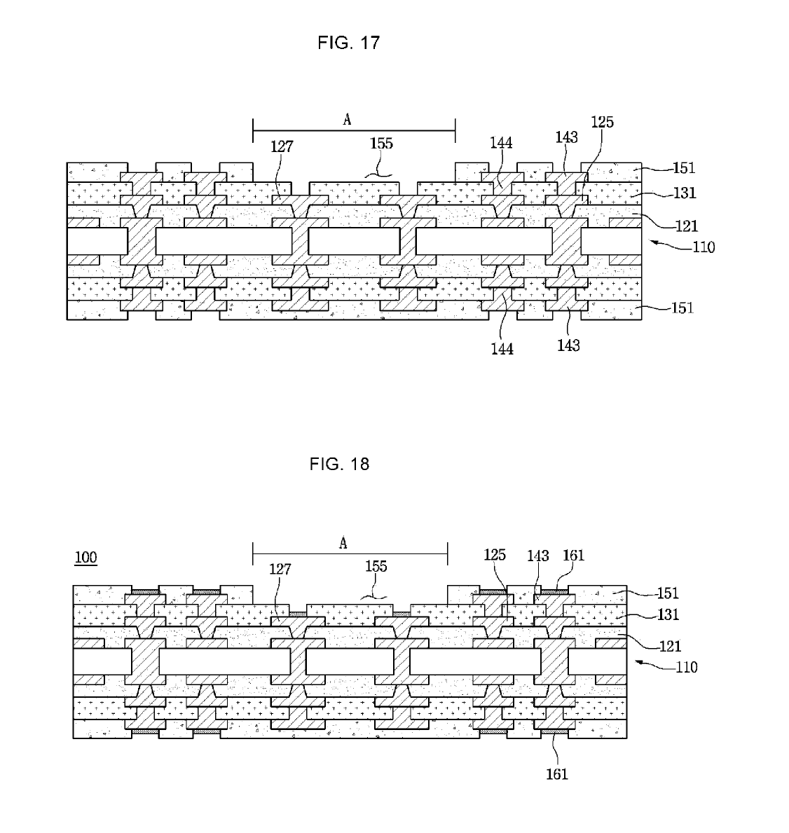

Referring to FIG. 17, the upper and lower protective layers 151 are formed (operation S140 in FIG. 2).

According to an embodiment, the upper protective layer 151 is formed above the upper second insulating layer 131 and to surround the upper second circuit layer 143. Similarly, the lower protective layer 151 is formed below the lower second insulating layer 131 and to surround the lower second circuit layer 143. Moreover, the upper protective layer 151 is formed in such a way that portions of the upper second circuit layer 143 that need to be electrically connected with an external component (not shown) are exposed to an outside.

Moreover, the upper protective layer 151 includes a tunnel type cavity 155 formed in the cavity area A. Accordingly, the upper second insulating layer 131 and the upper first circuit layer 125 in the cavity area A are exposed to the outside environment by the upper protective layer 151.

When the external component (not shown) and the upper second circuit layer 143 are electrically connected with each other, the upper protective layer 151 formed as described above protects adjacent portions of the upper second circuit layer 143 that is electrically connected with the external component. Moreover, the protective layers 151 prevent the second circuit layers 143 from being oxidized and corroded due to exposure to the outside.

According to an embodiment, the protective layers 151 are constructed of a heat-resistant coating material. For instance, the protective layers 151 may be constructed of a solder resist.

Referring to FIG. 18, the upper surface-treated layer 161 is formed on portions of an upper surface of the upper second circuit layer 143 that are exposed to the outside environment by the upper protective layer 151. In addition, the upper surface-treated layer 161 is formed on portions of an upper surface of the upper first circuit layer 125 that are exposed to the outside environment by the upper second insulating layer 131 in the cavity 155. That is, the upper surface-treated layer 161 is formed only on portions of upper faces of the connection pads 127 that are exposed to the outside environment by the second insulating layers 131. The lower surface-treated layer 161 is formed on portions of a lower surface of the lower second circuit layer 143 that are exposed to the outside environment by the lower protective layer 151.

According to an embodiment, the surface-treated layers 161 may include at least one of organic solderability preservatives (OSP), electroless nickel immersion gold (ENIG), nickel, palladium, gold, tin, lead-free solder, and silver. Moreover, the surface-treated layers 161 may be constructed of any other material known in the field of circuit boards that is capable of protecting an exposed circuit layer. Moreover, in case the second circuit layers 143 having the surface-treated layers 161 formed thereon need to be electrically connected with an outside element, the surface-treated layers 161 may be constructed of a conductive material among the above-described materials.

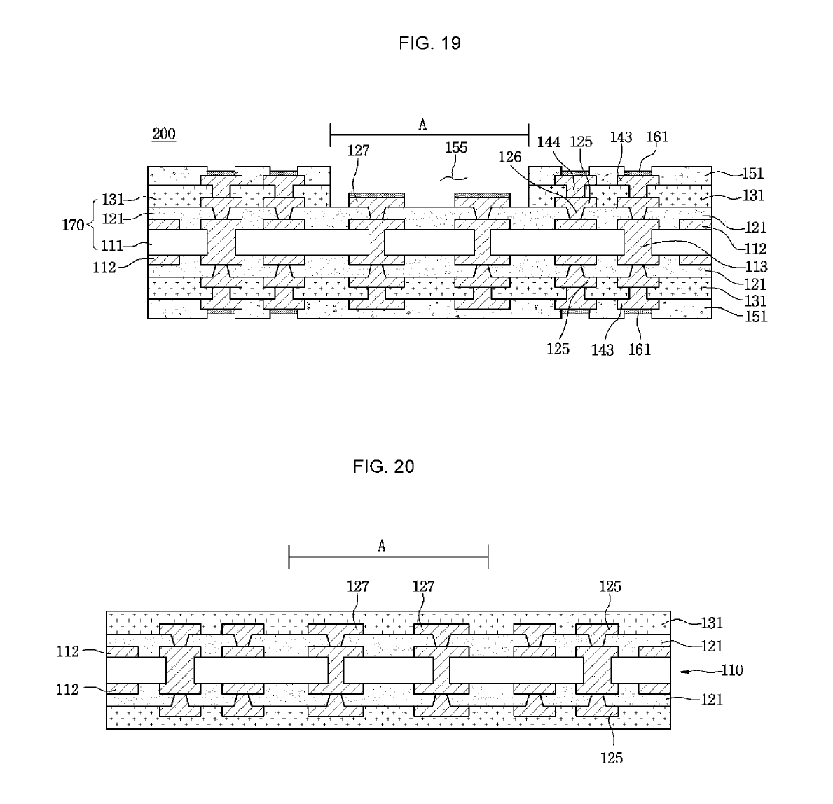

FIG. 19 illustrates an example of a printed circuit board 200 in accordance with another embodiment.

Referring to FIG. 19, the printed circuit board 200 includes an insulating layer 170, the upper and lower inner circuit layers 112, the upper and lower first circuit layers 125, the upper and lower second circuit layers 143, the upper and lower protective layers 151 and the upper and lower surface-treated layers 161.

Hereinafter, elements of the printed circuit board 200 that are different from the elements of the printed circuit board 100 will be primarily described. Therefore, the elements of the printed circuit board 200 that are identical to the elements of the printed circuit board 100 will not be redundantly described.

In the printed circuit board 200, the cavity 155 of the upper protective layer 151 is extended to the upper second insulating layer 131. Accordingly, the portions of the upper first insulating layer 121 and the upper first circuit layer 125 located below the cavity 155 are exposed to the outside environment by the cavity 155.

According to an embodiment, the upper surface-treated layer 161 is formed throughout the entire upper faces of the connection pads 127, which are formed by the upper first circuit layer 125, in the cavity 155.

FIGS. 20-22 are cross-sectional views illustrating example processes performed in a method of manufacturing the printed circuit board 200.

Referring to FIG. 20, the upper and lower first insulating layers 121, the upper and lower first circuit layers 125 and the upper and lower second insulating layers 131 are formed on the core board 110.

The core board 110, the first insulating layers 121, the first circuit layers 125 and the second insulating layers 131 may be formed through the same processes described with reference to FIGS. 3-10. Accordingly, the descriptions of these processes will not be redundantly provided herein.

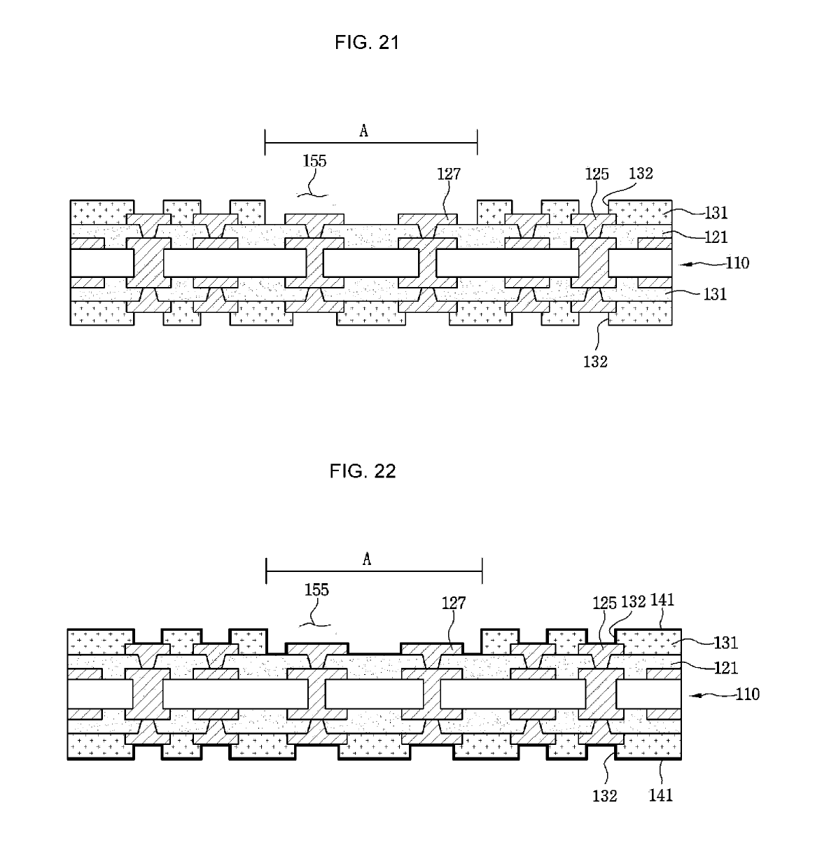

Referring to FIG. 21, the second insulating layers 131 are patterned by performing exposure and development processes. The upper second insulating layer 131 is patterned such that the portions of the upper first insulating layer 121 and the connection pads 127 in a cavity area A are exposed to the outside environment. More specifically, the upper faces and lateral faces of the connection pads 127 are exposed to the outside environment. Moreover, the upper and lower second via holes 132 are formed in areas of the upper and lower second insulating layers 131 excluding the cavity area A.

According to an embodiment, the second insulating layers 131 are constructed of a photosensitive material and are patterned using the exposure and development processes. Accordingly, since a conventional punched prepreg is not used, it is possible to omit heating and pressing processes for laminating the prepreg. Therefore, by using the upper second insulating layer 131 constructed of the photosensitive material, it is possible to prevent the problem caused by the prepreg flowing into the cavity area A when the prepreg is heated and pressed.

Moreover, the upper second insulating layer 131 functions as a solder resist layer for protecting the upper first circuit layer 125 in the cavity area A. That is, the upper second insulating layer 131 is substituted for a conventional solder resist layer for protecting the upper first circuit layer 125 in the cavity area A. Therefore, it is possible to omit an additional process of forming the solder resist layer in the cavity area A.

Referring to FIG. 22, the upper and lower seed layers 141 are formed.

According to an embodiment, on an upper side of the core board 110, the upper seed layer 141 is formed above the portions of the upper first insulating layer 121 exposed to the outside environment by the cavity 155, above the upper second insulating layer 131, on inner walls of the upper second via holes 132 and above the portions of the upper first circuit layer 125 exposed to the outside environment. On the lower side of the core board 110, the lower seed layer 141 is formed below the lower second insulating layer 131, on inner walls of the lower second via holes 132 and below the portions of the lower first circuit layer 125 exposed to the outside environment.

The seed layers 141 are formed using a method known in the field of circuit boards. For example, the seed layers 141 may be formed through a wet plating method such as, for example, electroless plating. Moreover, the seed layers 141 may be formed using a dry plating method such as, for example, sputtering.

Processes that follow thereafter are identical with the processes described with reference to FIGS. 13-17 and thus will not be redundantly described herein.

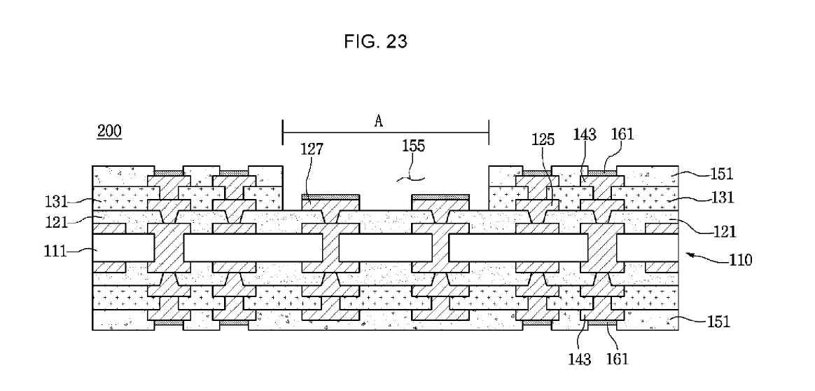

Referring to FIG. 23, upper and lower surface-treated layers 161 are formed.

The upper second insulating layer 131 is formed in areas excluding the cavity area A. Accordingly, the cavity 155 formed in the upper protective layer 151 is formed to be extended up to the upper second insulating layer 131.

The upper surface-treated layer 161 is formed above the portions of the upper second circuit layer 143 that are exposed to the outside environment by the upper protective layer 151. In addition, the upper surface-treated layer 161 is formed above the connection pads 127, which are portions of the upper first circuit layer 125 that are exposed to the outside environment by the cavity 155. In this example, the surface-upper treated layer 161 is formed throughout the entire upper faces of the connection pads 127.

According to an embodiment, the surface-treated layers 161 may include at least one of organic solderability preservatives (OSP), electroless nickel immersion gold (ENIG), nickel, palladium, gold, tin, lead-free solder, and silver. Moreover, the surface-treated layers 161 may be constructed of any other material known in the field of circuit boards that is capable of protecting an exposed circuit layer. Moreover, in case the second circuit layers 143 having the surface-treated layers 161 formed thereon need to be electrically connected with an outside element, the surface-treated layers 161 may be constructed of a conductive material among the above-described materials.

While this disclosure includes specific examples, it will be apparent to one of ordinary skill in the art that various changes in form and details may be made in these examples without departing from the spirit and scope of the claims and their equivalents. The examples described herein are to be considered in a descriptive sense only, and not for purposes of limitation. Descriptions of features or aspects in each example are to be considered as being applicable to similar features or aspects in other examples. Suitable results may be achieved if the described techniques are performed in a different order, and/or if components in a described system, architecture, device, or circuit are combined in a different manner, and/or replaced or supplemented by other components or their equivalents. Therefore, the scope of the disclosure is defined not by the detailed description, but by the claims and their equivalents, and all variations within the scope of the claims and their equivalents are to be construed as being included in the disclosure.

What is claimed is:

1. A printed circuit board comprising:
a first insulating layer;
a first circuit layer disposed above the first insulating layer;
a second insulating layer disposed above the first insulating layer;
a second circuit layer disposed above the second insulating layer and constructed of a photosensitive material; and
a protective layer disposed above the second insulating layer and surrounding the second circuit layer,
wherein the protective layer comprises a tunnel type cavity and exposes a portion of the second circuit layer to an outside environment, and
wherein the second insulating layer exposes a portion of the first circuit layer located below the cavity to the outside environment.

2. The printed circuit board of claim 1, wherein the second insulating layer is disposed above the entire first insulating layer.

3. The printed circuit board of claim 2, wherein the second insulating layer is exposed to the outside environment by the cavity.

4. The printed circuit board of claim 2, wherein the second insulating layer surrounds the first circuit layer below the cavity and exposes a portion of an upper surface of the first circuit layer to the outside environment.

5. The printed circuit board of claim 1, wherein the second insulating layer is disposed in an area above the first insulating layer excluding an area below the cavity.

6. The printed circuit board of claim 5, wherein the first insulating layer is exposed to the outside by the cavity.

7. The printed circuit board of claim 1, further comprising a surface-treated layer formed above the portion of the first circuit layer exposed to the outside environment and the portion of the second circuit layer exposed to the outside environment.

8. The printed circuit board of claim 1, wherein the first circuit layer forms a connection pad in the cavity.

9. A method of manufacturing a printed circuit board, comprising:
forming a first circuit layer above a first insulating layer comprising a cavity area;
forming a second insulating layer above the first insulating layer, the second insulating layer being constructed of a photosensitive material;
forming a second circuit layer in an area above the second insulating layer excluding the cavity area; and
forming a protective layer above the second insulating layer to surround the second circuit layer, the protective layer comprising a cavity formed in the cavity area,
wherein the protective layer is exposes a portion of the second circuit layer to an outside environment, and
wherein the second insulating layer exposes the first circuit layer to the outside environment in the cavity area.

10. The method of claim 9, wherein the forming of the second insulating layer comprises forming the second insulating layer above the entire first insulating layer.

11. The method of claim 10, wherein the forming of the protective layer comprises exposing the second insulating layer to the outside environment in the cavity.

12. The method of claim 10, wherein the forming of the second insulating layer comprises forming the second insulating layer to surround the first circuit layer in the cavity area and to expose a portion of an upper surface of the first circuit layer to the outside environment.

13. The method of claim 9, the forming of the second insulating layer comprises forming the second insulating layer in an area above the first insulating layer excluding the cavity area.

14. The method of claim 13, wherein the forming of the protective layer comprises exposing the first insulating layer to the outside by the cavity of the protective layer.

15. The method of claim 9, further comprising forming a surface-treated layer above the portion of the first circuit layer exposed to the outside environment and the portion of the second circuit layer exposed to the outside environment.

16. The method of claim 9, wherein the first circuit layer forms a connection pad in the cavity.
